(19) United States
(12) Patent Application Publication
(10) Pub. No.: US 2025/0329690 A1
(43) Pub. Date: Oct. 23, 2025

(54) MANAGING HIGH BANDWIDTH MEMORY DEVICES

(71) Applicant: Yangtze Memory Technologies Co., Ltd., Wuhan (CN)

(72) Inventors: Min WEN, Wuhan (CN); Zhen PAN, Wuhan (CN); Shu WU, Wuhan (CN)

(21) Appl. No.: 18/769,326

(22) Filed: Jul. 10, 2024

(30) Foreign Application Priority Data
Apr. 19, 2024 (CN) 202410480275.3

(51) Int. Cl. H01L 25/065; H01L 23/528; H10B 80/00

(52) U.S. Cl. CPC H01L 25/0657; H01L 23/5283; H10B 80/00; H01L 2225/06524

(57) ABSTRACT

The present disclosure relates to methods, devices, systems, and techniques for managing a high bandwidth memory (HBM). An example semiconductor device includes a control die and wafers stacked together along a first direction. Each of the wafers includes a semiconductor substrate extending along a second direction perpendicular to the first direction and semiconductor structures on a side of the semiconductor substrate. The control die is coupled to the semiconductor structures of each of the wafers by contact structures extending through a corresponding semiconductor substrate of at least one of the wafers along the first direction.

### CROSS-REFERENCE TO RELATED APPLICATIONS

This application claims priority to Chinese Patent Application No. 202410480275.3, filed on Apr. 19, 2024, which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

A high bandwidth memory (HBM) uses stacked memory devices to enable effective data movement and access. While using less power in a smaller form factor, HBM devices can achieve higher bandwidth. HBM devices have been applied to high-performance graphics accelerators, network devices, high-performance datacenter, artificial intelligence (AI) and machine learning (ML) training, and various supercomputers.

### SUMMARY

The present disclosure describes methods, devices, systems and techniques for managing high bandwidth memory (HBM).

One aspect of the present disclosure features a semiconductor device that includes a control die and wafers stacked together along a first direction. Each of the wafers can include a semiconductor substrate extending along a second direction perpendicular to the first direction and semiconductor structures on a side of the semiconductor substrate. The control die is coupled to the semiconductor structures of each of the wafers by contact structures extending through a corresponding semiconductor substrate of at least one of the wafers along the first direction.

In some implementations, for each wafer of the wafers, each of the semiconductor structures of the wafer includes at least a part monolithically fabricated on the semiconductor substrate of the wafer.

In some implementations, the semiconductor structures include a first row of semiconductor structures arranged along the second direction.

In some implementations, the semiconductor structures further include a second row of semiconductor structures arranged along the second direction. The first row of semiconductor structures is adjacent to the second row of semiconductor structures along a third direction perpendicular to the first direction and the second direction.

In some implementations, one of the semiconductor structures of the wafer includes transistors formed from the semiconductor substrate of the wafer.

In some implementations, the control die is stacked with the wafers by die-to-wafer bonding.

In some implementations, the wafers include a first wafer and a second wafer. The semiconductor device further includes an interconnect layer between the second wafer and the control die and a first bonding layer between the interconnect layer and the control die. The interconnect layer is coupled to the control die and the contact structures. The first bonding layer includes first conductive bonding contacts and a first dielectric material isolating the first conductive bonding contacts.

In some implementations, the semiconductor device further includes a second bonding layer between the first wafer and the second wafer. The second bonding layer includes a second dielectric material and excludes a conductive bonding contact.

In some implementations, the contact structures include a first group of contact structures and a second group of contact structures. The control die is coupled to the semiconductor structures of the first wafer by the first group of contact structures extending through a semiconductor substrate of the first wafer and a semiconductor substrate of the second wafer. The control die is coupled to the semiconductor structures of the second wafer by the second group of contact structures extending through the semiconductor substrate of the second wafer.

In some implementations, each of the second group of contact structures contacts a conductive layer of one of the semiconductor structures of the second wafer, and each of the first group of contact structures contacts a conductive layer of one of the semiconductor structures of the first wafer without extending through a conductive layer in the second wafer.

In some implementations, the semiconductor device further includes a dielectric layer in contact with the interconnect layer and conductive pads in the dielectric layer. The dielectric layer is adjacent to the control die along the second direction. The conductive pads are coupled to the interconnect layer and are exposed from a surface of the dielectric layer.

In some implementations, the control die is configured to disable a semiconductor structure of a wafer of the wafers in response to detecting a defect of the semiconductor structure.

Another aspect of the present disclosure features a semiconductor device including a control die and one or more wafers stacked along a first direction. Each of the one or more wafers includes a semiconductor substrate extending along a second direction perpendicular to the first direction and semiconductor structures on a side of the semiconductor substrate. The semiconductor structures include rows of semiconductor structures. The control die is coupled to the semiconductor structures of each of the wafers by contact structures extending through a corresponding semiconductor substrate of the one or more wafers along the first direction.

In some implementations, the rows of semiconductor structures include a first row of semiconductor structures arranged along the second direction and a second row of semiconductor structures arranged along the second direction. The first row of semiconductor structures is adjacent to the second row of semiconductor structures along a third direction perpendicular to the first direction and the second direction.

In some implementations, the wafers include a first wafer and a second wafer. The semiconductor device further includes an interconnect layer between the second wafer and the control die, a first bonding layer between the interconnect layer and the control die, and a second bonding layer between the first wafer and the second wafer. The interconnect layer is coupled to the control die and the contact structures. The first bonding layer includes first conductive bonding contacts and a first dielectric material isolating the first conductive bonding contacts. The second bonding layer includes a second dielectric material and excludes a conductive bonding contact.

In some implementations, the contact structures include a first group of contact structures and a second group of contact structures. The control die is coupled to the semiconductor structures of the first wafer by the first group of contact structures extending through a semiconductor substrate of the first wafer and a semiconductor substrate of the second wafer. The control die is coupled to the semiconductor structures of the second wafer by the second group of contact structures extending through the semiconductor substrate of the second wafer.

A further aspect of the present disclosure features a method including stacking wafers along a first direction, where each of the wafers includes a group of semiconductor structures arranged along a second direction perpendicular to the first direction. The method further includes forming contact structures extending along the first direction and stacking at least one control die on the wafers along the first direction. The group of semiconductor structures in each of the wafers is coupled to the at least one control die through at least one of the contact structures.

In some implementations, the method further includes forming an interconnect layer on top of the wafers, where the at least one control die is stacked on the interconnect layer.

In some implementations, the wafers include a first wafer and a second wafer stacked on the first wafer. The group of semiconductor structures of the first wafer includes a first semiconductor structure and a second semiconductor structure. The group of semiconductor structures of the second wafer includes a third semiconductor structure and a fourth semiconductor structure. The contact structures include a first contact structure, a second contact structure, a third contact structure, and a fourth contact structure coupled to the first semiconductor structure, the second semiconductor structure, the third semiconductor structure, and the fourth semiconductor structure, respectively.

In some implementations, the method further includes bonding a bonding layer of the second wafer to a bonding layer of the first wafer, where the bonding layer of the first wafer and the bonding layer of the second wafer each include a dielectric material and excludes a conductive bonding contact.

In some implementations, the third contact structure extends into the second wafer and contacts a conductive layer of the third semiconductor structure without extending through the bonding layer of the second wafer. The fourth contact structure extends into the second wafer and contacts a conductive layer of the fourth semiconductor structure without extending through the bonding layer of the second wafer. The first contact structure extends through the bonding layer of the second wafer and the bonding layer of the first wafer and contacts a conductive layer of the first semiconductor structure without extending through the conductive layer of the third semiconductor structure. The second contact structure extends through the bonding layer of the second wafer and the bonding layer of the first wafer and contacts a conductive layer of the second semiconductor structure without extending through the conductive layer of the fourth semiconductor structure.

In some implementations, the method further includes bonding the first wafer to a carrier wafer.

In some implementations, the method further includes thinning the first wafer by thinning a substrate of the first wafer and thinning the second wafer by thinning a substrate of the second wafer.

In some implementations, each of the at least one control die and the interconnect layer includes a bonding layer including conductive bonding contacts and a dielectric material isolating the conductive bonding contacts. The method further includes bonding the at least one control die to the interconnect layer by bonding the dielectric material of the bonding layer of the at least one control die to the dielectric material of the bonding layer of the interconnect layer and bonding the conductive bonding contacts of the bonding layer of the at least one control die to the conductive bonding contacts of the bonding layer of the interconnect layer.

In some implementations, the wafers include a third wafer stacked on the second wafer along the first direction.

In some implementations, the method further includes forming a dielectric layer on top of the interconnect layer, where the dielectric layer is adjacent to the at least one control die along the second direction. The method further includes forming conductive pads in the dielectric layer, where the conductive pads are coupled to the interconnect layer and are exposed from a top surface of the dielectric layer. The method further includes forming an integrated structure including the at least one control die, the wafers, the interconnect layer, and the dielectric layer. The method further includes cutting off a part of the integrated structure to be a semiconductor device. The semiconductor device includes a corresponding control die of the at least one control die, a corresponding part of the dielectric layer, a corresponding part of the interconnect layer, and a corresponding part of the group of semiconductor structures of each of the wafers.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIGS. 1A-1D illustrate example semiconductor devices.

FIGS. 2A-2O illustrate an example process of manufacturing a semiconductor device.

FIG. 3 illustrates a flow chart of an example process of manufacturing a semiconductor device.

Like reference numbers and designations in the various drawings indicate like elements. It is also to be understood that the various exemplary implementations shown in the figures are merely illustrative representations and are not necessarily drawn to scale.

### DETAILED DESCRIPTION

Implementations of the present disclosure provide techniques for managing high bandwidth memory (HBM), e.g., forming a semiconductor device (such as a memory) including a control die and wafers. The wafers can be stacked together. Each of the wafers can include a semiconductor substrate and semiconductor structures on a side of the semiconductor substrate. The control die can be coupled to the semiconductor structures of each wafer by contact structures. The contact structure can extend through a semiconductor substrate of at least one of the wafers.

Implementations of the present disclosure can provide one or more of the following technical advantages and/or benefits. The semiconductor structures can be integrated into the semiconductor device at a wafer level without being dice into individual dies. The semiconductor device can be formed using wafer-to-wafer bonding instead of die-to-die bonding, thereby reducing the fabrication cost and increasing the production yield. Compared to the die-to-dic bonding, the wafer-to-wafer bonding and/or the dic-to-wafer bonding techniques allow the semiconductor device to have a large number of semiconductor structures with small pitches. In addition, each wafer can be thinned by decreasing a thickness of the semiconductor substrate of the wafer, thereby reducing a size of the semiconductor device. The control die can include control and test logic configured to detect a defect of a semiconductor structure (e.g., bad die) of the semiconductor device and disable the defective semiconductor structure. In this way, while one or more semiconductor structures of the semiconductor device are not working, the rest part of the semiconductor device can still function properly, thereby improving the reliability and robustness of the semiconductor device. Furthermore, different plane regions of a single memory die (e.g., DRAM) can operate independently. When multiple memory devices are integrated into a 3D HBM, logic circuits (e.g., a control die) can be used to bypass or disable defective regions of the memory devices. This situation can be achieved directly through stacking wafers that include memory devices using wafer-to-wafer bonding, thereby eliminating the need for cutting a wafer into dies and using Know Good Die (KGD) techniques to remove defective memory devices before stacking. The control die can be integrated into the 3D HBM through die-to-wafer bonding. Combining the die-to-wafer bonding with a corresponding interconnect layer allows different numbers of memory devices to be integrated simply by changing the corresponding control die and interconnect layer. By effectively utilizing wafer-to-wafer bonding in combination with the interconnect layer and the control die, a range of the product category can be enriched, and manufacturing costs can be reduced compared to traditional HBM. Compared to KGD techniques, the wafer-to-wafer bonding technique can avoid bad dies through design and can achieve higher levels of integration.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

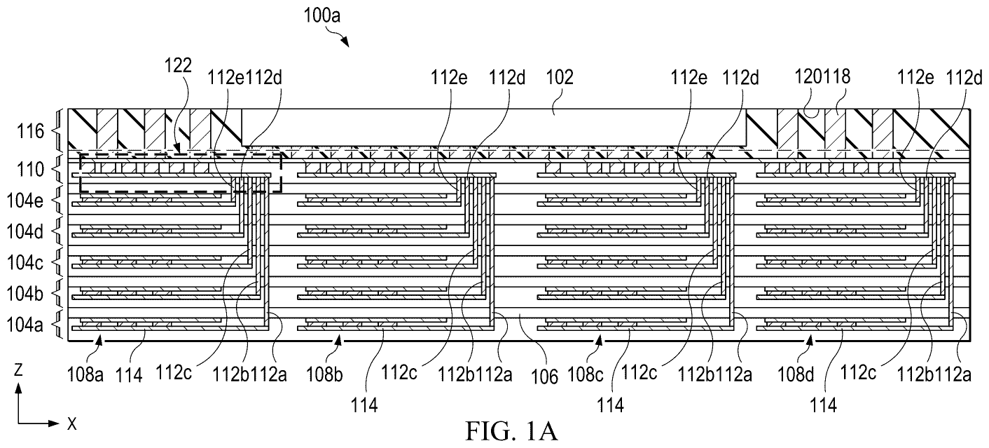

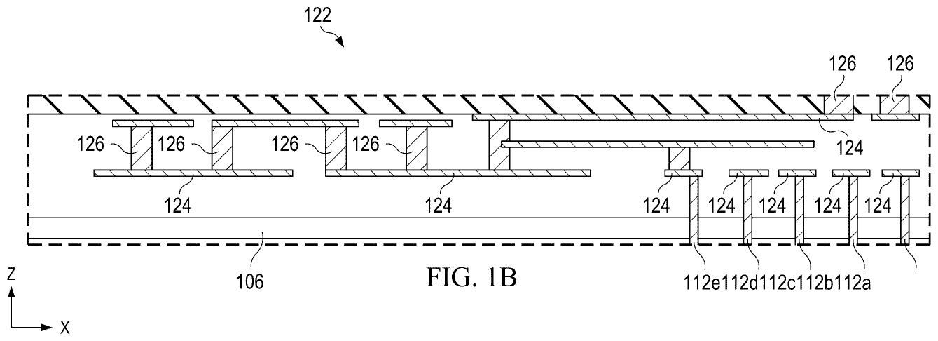

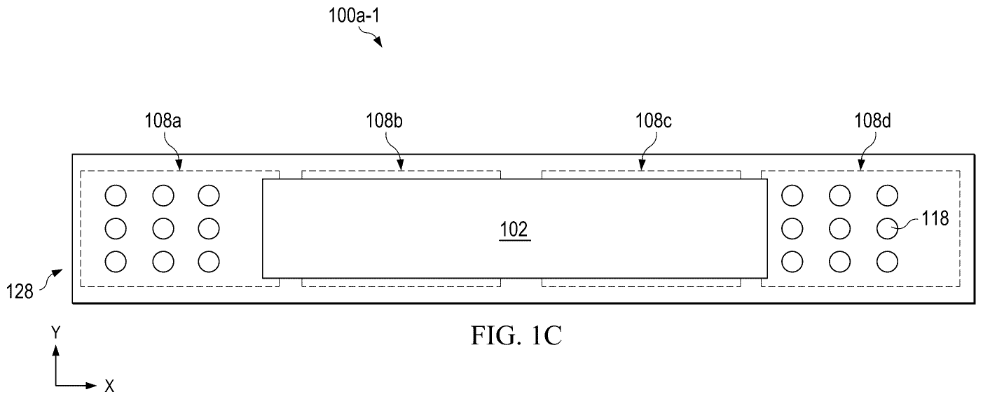

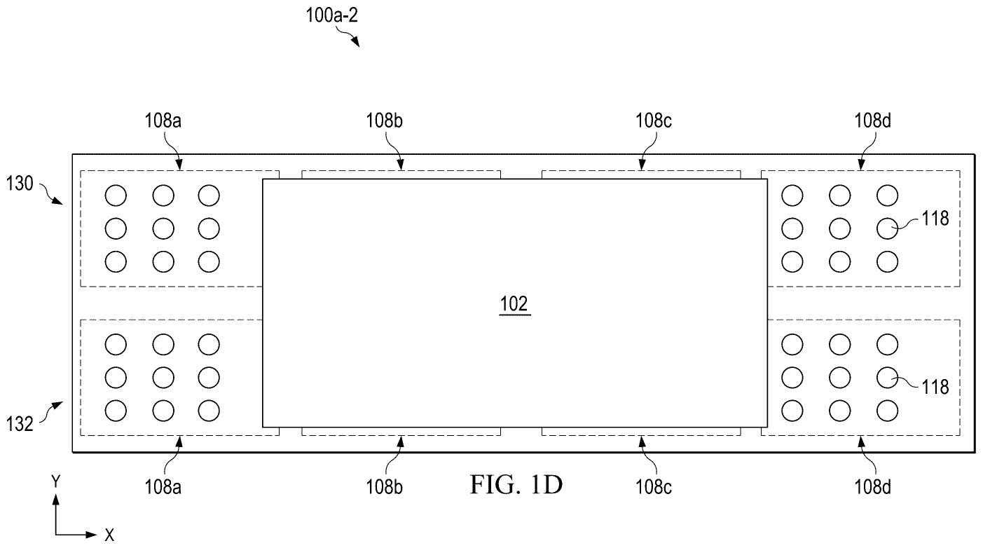

FIG. 1A illustrates a side view of an example semiconductor device 100a. It is understood that FIG. 1A is for illustrative purposes only and may not necessarily reflect the actual device structure (e.g., interconnections) in practice.

It is noted that X, Y, and Z axes (also referred to as X, Y, and Z directions) are included in FIG. 1A to further illustrate the spatial relationship of various components in a semiconductor device. A substrate of the semiconductor device includes two lateral surfaces extending laterally in the X-Y plane: a top surface on the front side of a wafer on which a component of the semiconductor device can be formed, and a bottom surface on the backside opposite to the front side of the wafer. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

As shown in FIG. 1A, the semiconductor device 100a includes a control die 102 and wafers 104a-104c. The wafers 104a-104c can be stacked together along a vertical direction (e.g., the Z direction). Each of the wafers 104a-104e can include a semiconductor substrate 106 extending along a horizontal direction (e.g., the X direction). The semiconductor substrates 106 can include any suitable semiconductor materials, such as monocrystalline, polycrystalline or single crystalline semiconductors. For example, the semiconductor substrates 106 can include silicon, silicon germanium (SiGe), germanium (Ge), gallium arsenide (GaAs), silicon on insulator (SOI), germanium on insulator (GOI), gallium nitride, silicon carbide, III-V compound, or any combinations thereof. Each wafer of the wafers 104a-104c can include semiconductor structures 108a-108d on a side of the semiconductor substrate of the wafer. The semiconductor device 100a can further include an interconnect layer 110 between the wafer 104c and the control die 102 along the vertical direction. The interconnect layer 110 can be coupled to contact structures 112a-112c extending along the vertical direction. The contact structures 112a-112e can extend through a corresponding semiconductor substrate (e.g., the semiconductor substrate 106 of the wafer 104c) of at least one of the wafers 104a-104c along the vertical direction. The control die 102 can be coupled to the semiconductor structures 108a-108d of each of the wafers 104a-104c through the interconnect layer 110 and the contact structures 112a-112c.

In some implementations, each of the wafers 104a-104c can be a smaller wafer cut out from an entire piece of a larger wafer. For example, the larger wafer can be one wafer or multiple wafers bonded together. Each of the semiconductor structures 108a-108d of the wafers 104a-104c include a fully functional electronic circuit, which can be a microprocessor, memory, sensor, or any other suitable type of integrated circuit (IC) chip. In some implementations, the semiconductor structures 108a-108d of the wafers 104a-104c can include the same type of IC chips. For example, the semiconductor structures 108a-108d of the wafers 104a-104c can be memory devices such as dynamic random-access memories (DRAMs). In another example, the semiconductor structures 108a-108d of the wafers 104a-104c can be processors such as central processing units (CPUs) or graphics processing units (GPUs). In some implementations, different wafers can include different types of IC chips. For example, the semiconductor structures 108a-108d of the wafer 104a can be memory devices, and the semiconductor structures 108a-108d of the wafer 104b can be processors. In some implementations, the semiconductor structures of the same wafer can be different types of IC chips. For example, the semiconductor structure 108a of the wafer 104a can be a processor, and the semiconductor structure 108b-108d of the wafer 104a can be memory devices. It is understood that while these examples are merely for illustration purposes, in practice any suitable combinations or arrangements can be applied to the semiconductor structures.

In some implementations, for each wafer of the wafers 104a-104e, each semiconductor structure (e.g., 108a-108d) of the wafer can be monolithically fabricated on at least a part of the semiconductor substrate 106 of the wafer.

In some implementations, for each wafer of the wafers 104a-104c, each semiconductor structure (e.g., 108a-108d) of the wafer can include transistors formed from the semiconductor substrate 106 of the wafer. For example, the semiconductor structures 108a-108d of the wafer can be DRAMs. Each DRAM cell of the semiconductor structures 108a-108d can include a respective transistor. A semiconductor body of the transistor can be formed from the semiconductor substrate 106 of the wafer (e.g., by etching or epitaxy growing).

The contact structures 112a-112e can include multiple groups of contact structures. Each group of contact structures can be coupled to the semiconductor structures of a corresponding wafer. For example, the contact structures 112a are respectively coupled to semiconductor structures 108a-108d of the wafer 104a. The contact structures 112b are respectively coupled to semiconductor structures 108a-108d of the wafer 104b. The contact structures 112c are respectively coupled to semiconductor structures 108a-108d of the wafer 104c. The contact structures 112d are respectively coupled to semiconductor structures 108a-108d of the wafer 104d. The contact structures 112e are respectively coupled to semiconductor structures 108a-108d of the wafer 104c.

Each group of contact structures can extend through one or more semiconductor substrates. For example, the contact structures 112a extend through the semiconductor substrates 106 of the wafers 104a-104c. The contact structures 112b extend through the semiconductor substrates 106 of the wafers 104b-104c. The contact structures 112c extend through the semiconductor substrates 106 of the wafers 104c-104c. The contact structures 112d extend through the semiconductor substrates 106 of the wafers 104d-104c. The contact structures 112e extend through the semiconductor substrates 106 of the wafer 104c.

In some implementations, each of contact structures 112a-112e can be coupled to a conductive layer 114 of a corresponding semiconductor structure (e.g., 108a-108d). In some implementations, the conductive layer 114 of a semiconductor structure can be configured to provide one or more of power supplies, clock signals, or data path signals to the semiconductor structure. In some implementations, the conductive layers 114 can be arranged in a staircase-like structure, such that each of contact structures 112a-112e can contact or can be connected to a conductive layer of a corresponding semiconductor structure without extending through a conductive layer of another semiconductor structure. For example, the contact structure 112a that is connected to the conductive layer 114 of the semiconductor structure 108a of the wafer 104a does not extend through the conductive layers 114 of the semiconductor structures 108b-108d of the wafer 104a. The contact structure 112a that is connected to the conductive layer 114 of the semiconductor structure 108a of the wafer 104a also does not extend through the conductive layers 114 of the semiconductor structures 108a of the wafers 104b-104c.

In some implementations, adjacent wafers of the wafers 104a-104e can be bonded through a respective bonding layer using direct dielectric-dielectric bonding. For example, the wafer 104a and the wafer 104b can be bonded through a bonding layer (not shown in FIG. 1A) between the wafer 104a and the wafer 104b along the vertical direction. The bonding layer can include one or more dielectric materials and can exclude a conductive bonding pad. That is, the bonding layer can be an isolating layer between the adjacent wafers.

In some implementations, the control die 102 and the interconnect layer 110 can be bonded through a bonding layer using hybrid dielectric-dielectric and metal-metal bonding. For example, the control die 102 and the interconnect layer 110 can be bonded through a bonding layer between the control die 102 and the interconnect layer 110 along the vertical direction. The bonding layer can include conductive bonding contacts and a dielectric material isolating the conductive bonding contacts. The conductive bonding contact can include conductive materials including, but not limited to, tungsten (W), cobalt (Co), copper (Cu), aluminum (Al), silicides, or any combination thereof. The dielectric material can include dielectrics including, but not limited to, silicon oxide, silicon nitride, silicon oxynitride, low-k dielectrics, or any combination thereof.

As shown in FIG. 1A, the semiconductor device 100a can further include a dielectric layer 116. The dielectric layer 116 is in contact with the interconnect layer 110 along the vertical direction. The dielectric layer 116 is adjacent to the control die 102 along a horizontal direction (e.g., the X direction). The dielectric layer 116 can include conductive pads 118 that are coupled to the interconnect layer 110. The conductive pads 118 can be exposed from a surface 120 of the dielectric layer 116. The surface 120 of the dielectric layer 116 is not in contact with the interconnect layer 110. The conductive pads 118 can be coupled to an external device. The conductive pads 118 can be configured to provide connections between one or more of the control die 102 and the semiconductor structures 108a-108d of the wafers 104a-104e and the external device.

In some implementations, the control die 102 can include buffer circuitry and/or test logic for the semiconductor structures 108a-108d of the wafers 104a-104c. For example, the control die 102 can be configured to detect a defect of one or more of the semiconductor structures 108a-108d of the wafers 104a-104c. In some instances, in response to detecting the defect of one of the semiconductor structures, the control die 102 is configured to disable the corresponding semiconductor structure that has the defect. In this way, while one or more semiconductor structures of the semiconductor device 100a are not working, other semiconductor structures of the semiconductor device 100a can still function properly. In some implementations, the semiconductor device 100a can be categorized into different grades based on one or more of the following factors. The factors can include whether any semiconductor structure of the semiconductor device 100a has a defect, what type of defect the semiconductor structure has, and a quantity of defective semiconductor structures in the semiconductor device 100a. For example, the semiconductor structures of the semiconductor device 100a can be storage devices such as DRAMs or NAND flash memories. If a larger number of semiconductor structures of the semiconductor device 100a are defective, the semiconductor device 100a may have a reduced performance (e.g., a smaller storage capacity or a slower read/write speed). Thus, the semiconductor device 100a can be categorized to a lower grade.

In some implementations, the semiconductor structures 108a-108d of the wafers 104a-104e can be memory devices. The external device can be a logic device and can include at least one processor of an electronic device, such as a central processing unit (CPU), a graphics processing unit (GPU), an application-specific integrated circuit (ASIC), or a system-on-chip (SoC), such as an application processor (AP). The external device can be configured to send or receive data to or from the semiconductor structures 108a-108d of the wafers 104a-104c. The control die 102 can be configured to provide physical layer communication protocols (e.g., IEEE-1500) between the semiconductor structures 108a-108d of the wafers 104a-104e and the external device. The control die 102 can be configured to transmit data between the semiconductor structures 108a-108d of the wafers 104a-104c and the external device based on control commands and addresses from the external device.

In some implementations, the external device can be directly connected to the control die 102. In some other implementations, the external device can be coupled to the control die 102 through an interface. The interface can include connections provided by the conductive pads 118 or an interposer. In practice, the interface and/or the interposer can be provided by any suitable techniques.

FIG. 1B illustrates an enlarged view of a part 122 of the interconnect layer 110 in the semiconductor device 100a of FIG. 1A. The interconnect layer 110 can include interconnects (also referred to herein as “contacts”), including lateral interconnect lines 124 and vertical interconnect access (VIA) contacts 126. The contact structures 112a-112e can be coupled to respective interconnects in the interconnect layer 110. As used herein, the term “interconnects” can broadly include any suitable types of interconnects, such as middle-end-of-line (MEOL) interconnects and back-end-of-line (BEOL) interconnects. The interconnect layer 110 can further include one or more interlayer dielectric (ILD) layers (also known as “intermetal dielectric (IMD) layers”) in which the interconnect lines 124 and VIA contacts 126 can form. That is, the interconnect layer 110 can include interconnect lines 124 and VIA contacts 126 in multiple ILD layers. The interconnect lines 124 and VIA contacts 126 in the interconnect layer 110 can include conductive materials including, but not limited to, tungsten (W), cobalt (Co), copper (Cu), aluminum (Al), silicides, or any combination thereof. The ILD layers in the interconnect layer 110 can include dielectric materials including, but not limited to, silicon oxide, silicon nitride, silicon oxynitride, low dielectric constant (low-k) dielectrics, or any combination thereof.

In some implementations, the semiconductor structures 108a-108d of each wafer can be arranged in an array perpendicular to the vertical direction (e.g., in the X-Y plane). The array can include one or more rows of semiconductor structures. FIG. 1C illustrates a top view of an example semiconductor device 100a-1. The semiconductor device 100a-1 can be an example of the semiconductor device 100a, where an array of semiconductor structures of each wafer includes one single row 128. The row 128 includes semiconductor structures 108a-108d arranged along the X direction. In some implementations, the semiconductor structures 108a-108d can be spaced along the X direction.

FIG. 1D illustrates a top view of an example semiconductor device 100a-2. The semiconductor device 100a-2 can be another example of the semiconductor device 100a, where an array of semiconductor structures of each wafer includes multiple rows (e.g., a row 130 and a row 132 as shown in FIG. 1D). Each of the rows 130 and 132 includes semiconductor structures 108a-108d arranged along the X direction. In some implementations, the semiconductor structures 108a-108d can be spaced along the X direction. The row 130 and the row 132 can be adjacent to each other along the Y direction. For each wafer of the wafers 104a-104c (as shown in FIG. 1A), the control die 102 can be coupled to semiconductor structures in the row 130 and semiconductor structures in the row 132 through corresponding contact structures (e.g., the contact structures 112a-112e as shown in FIG. 1A).

While FIGS. 1A-1D illustrate semiconductor devices that include a specific number of wafers (e.g., the wafers 104a-104c), it is understood that these examples are for illustration purposes only and that in practice any suitable number of wafers, such as one single wafer or multiple wafers (e.g., more than five), can be applicable. For similar reasons, in practice, any suitable number of semiconductor structures along either the X direction or the Y direction can be included in each wafer.

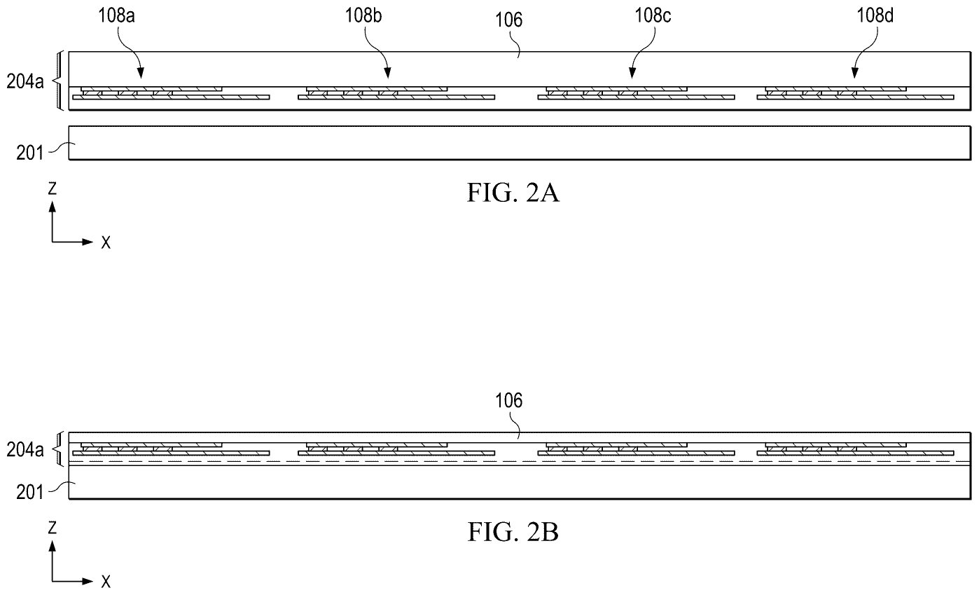

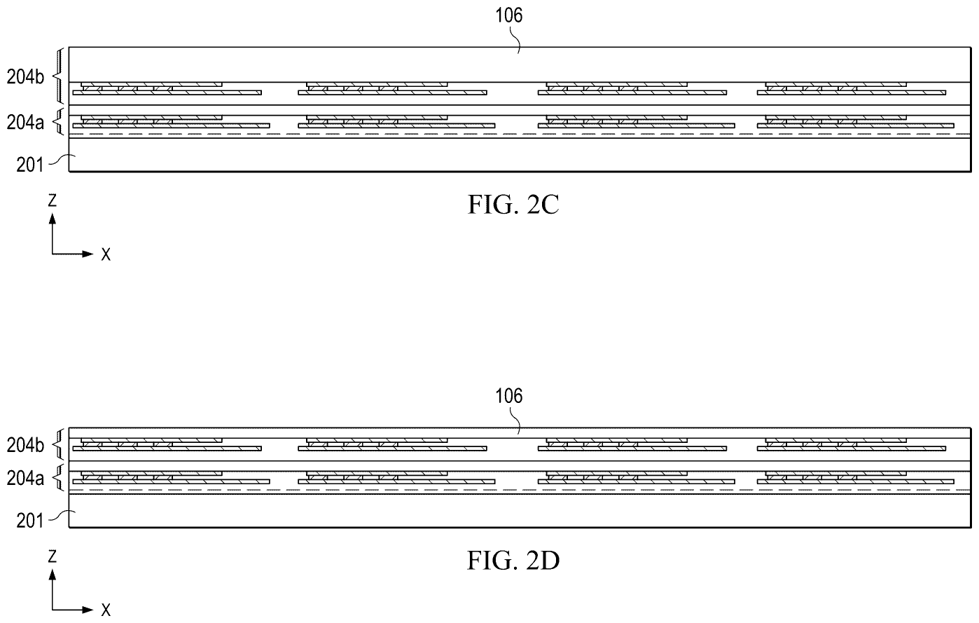

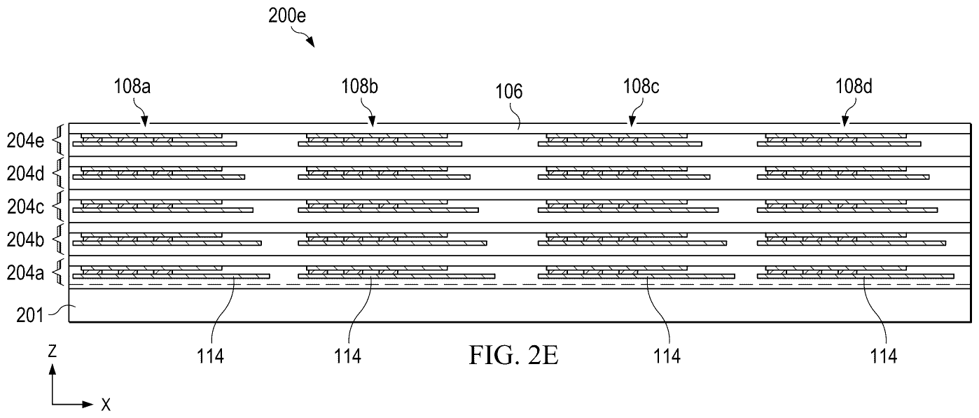

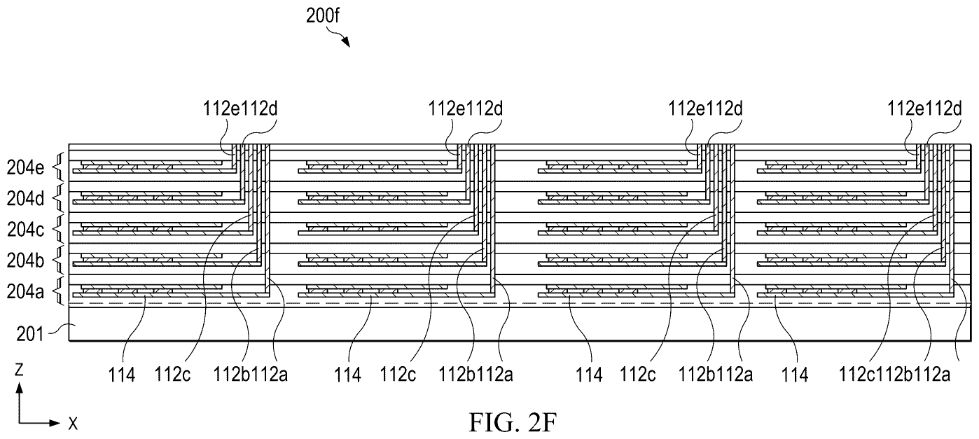

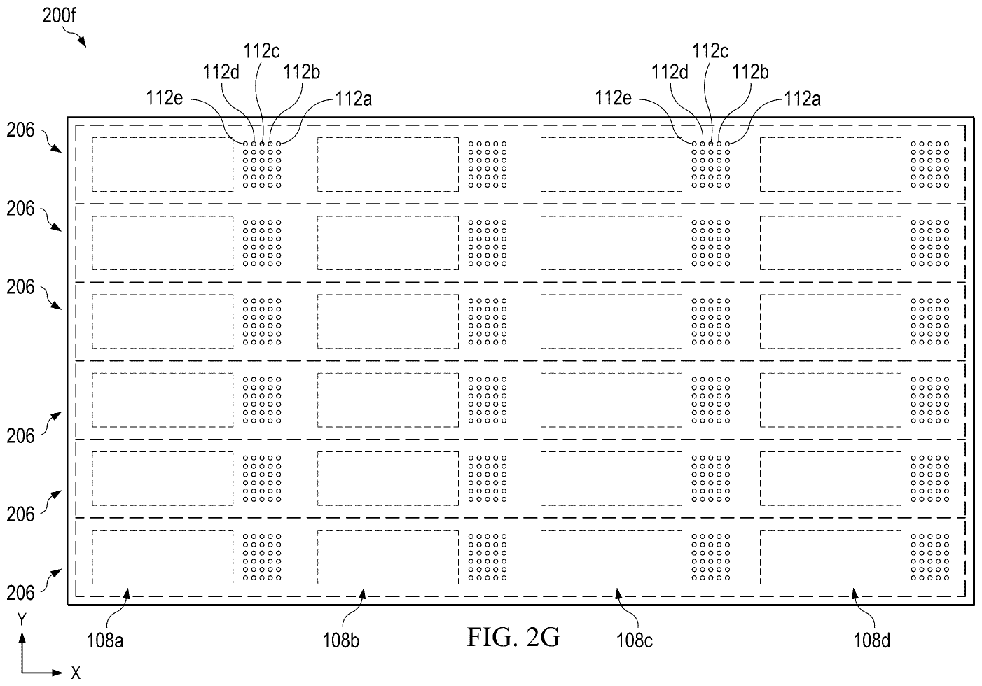

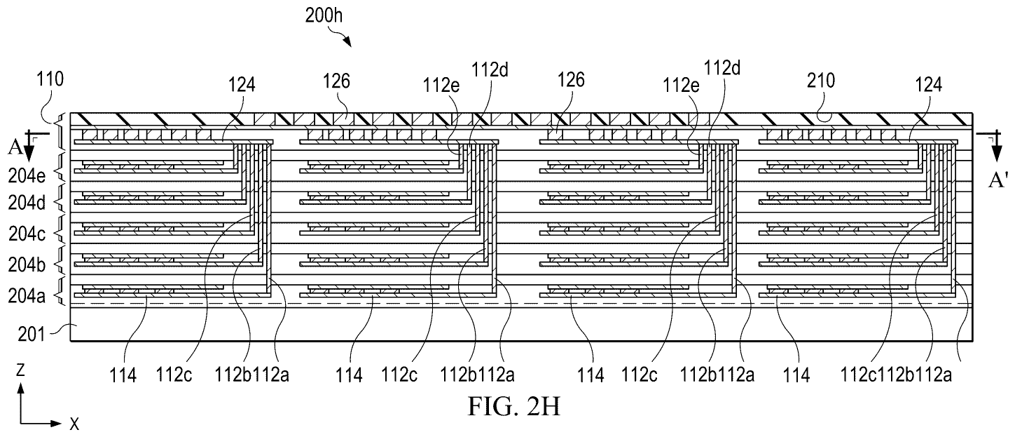

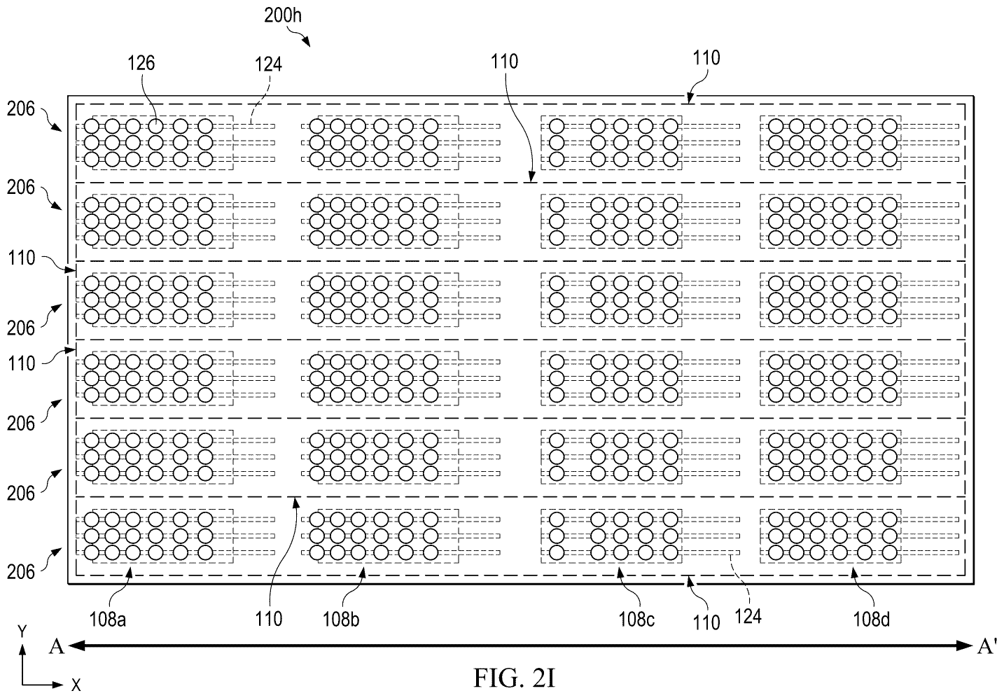

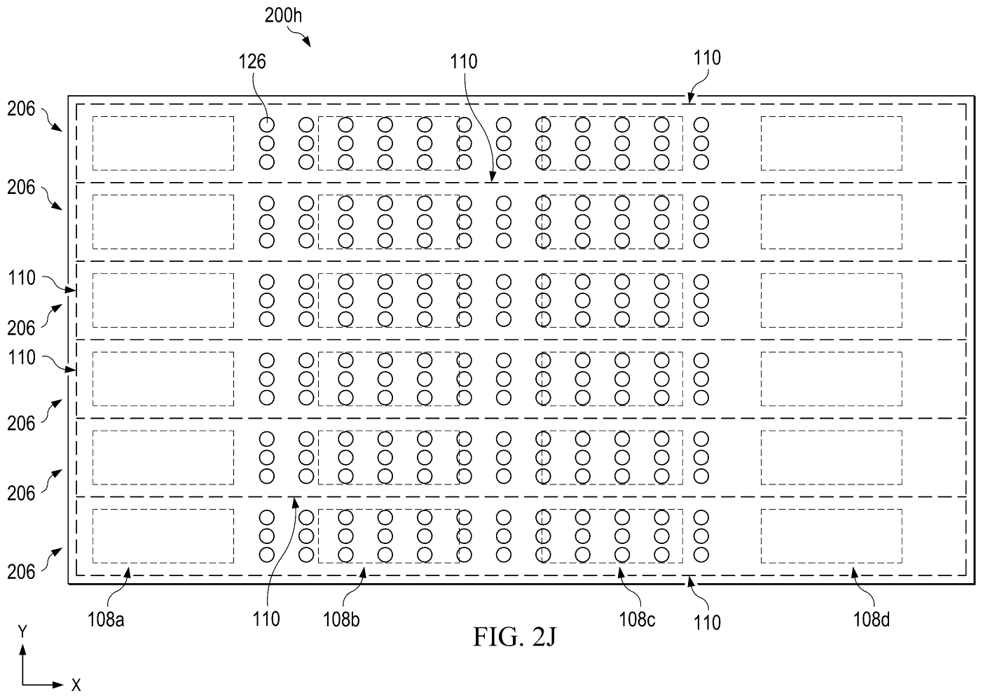

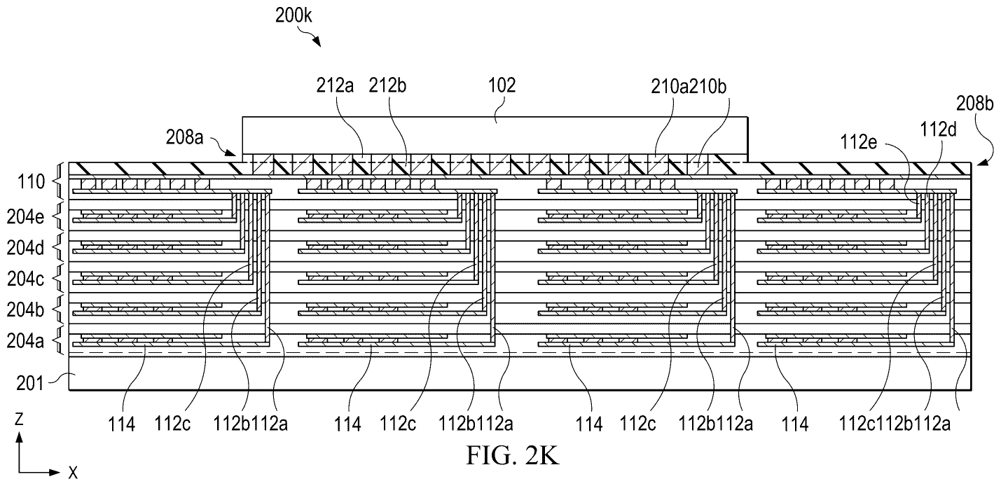

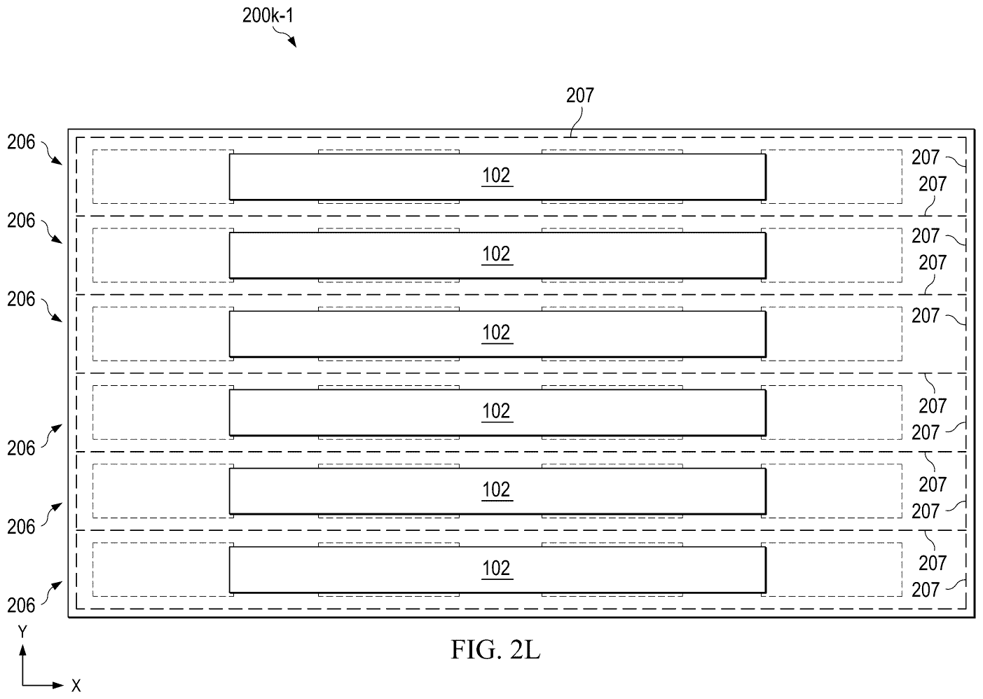

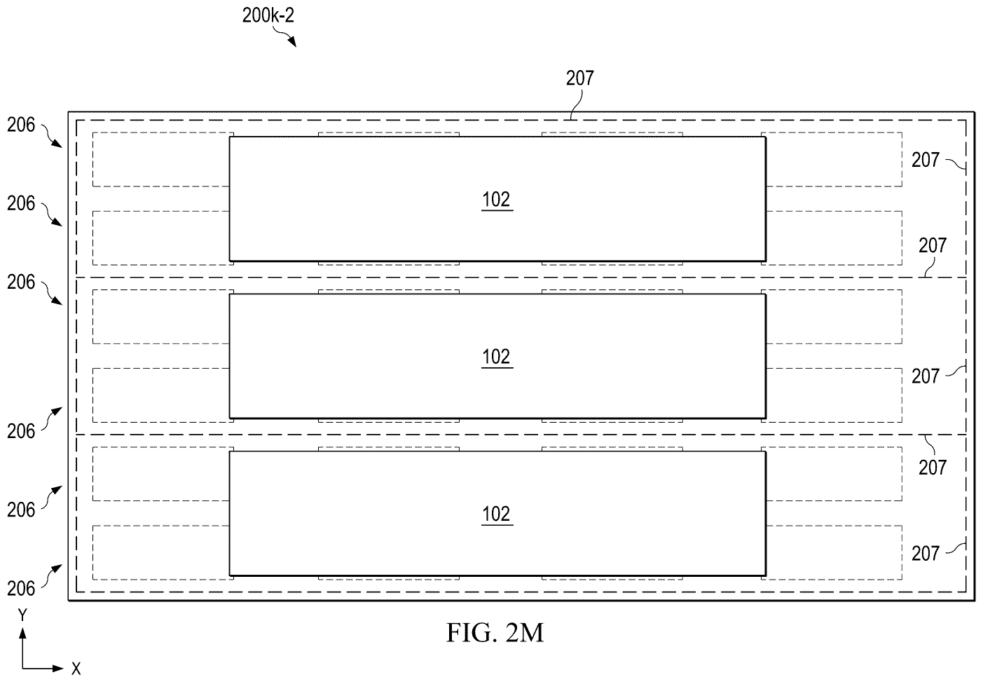

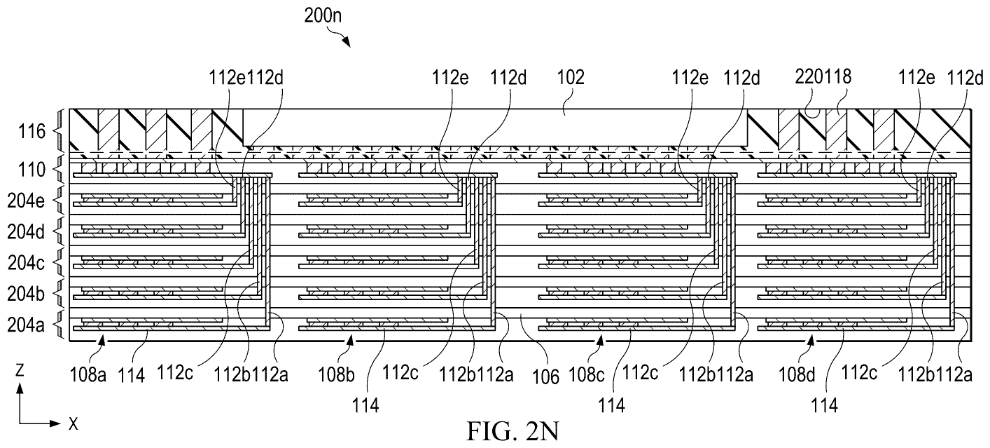

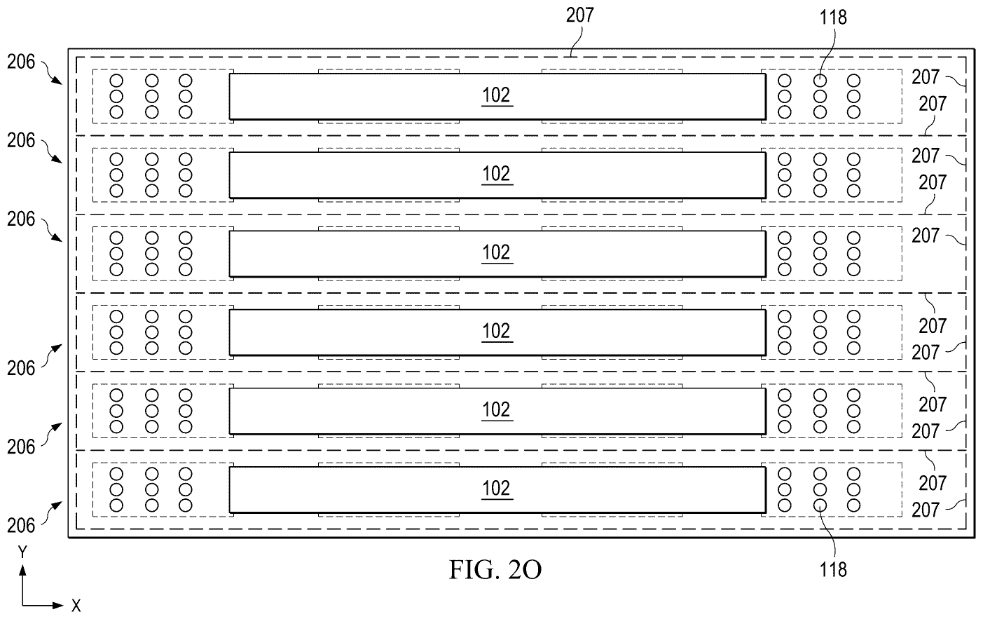

FIGS. 2A-2O illustrate an example process of fabricating a semiconductor device, such as the semiconductor device 100a, 100a-1, or 100a-2 as illustrated in FIGS. 1A-1D.

As shown in FIG. 2A, a wafer 204a is stacked on a carrier wafer 201. The wafer 204a can be bonded to the carrier wafer 201. The wafer 204a can be an entire piece of wafer or a larger piece of wafer that includes multiple wafers 104a (as shown in FIG. 1A). For example, the multiple wafers 104a in the wafer 204a can be arranged along the Y direction. In some implementations, the wafer 204a can be cut and diced into multiple pieces in a later process described with reference to FIG. 2O, and each piece is the same as or similar to the wafer 104a of FIG. 1A. The wafer 204a can include a semiconductor substrate 106 and semiconductor structures 108a-108d. In some implementations, a surface of the wafer 204a that is farther away from the semiconductor substrate 106 is bonded to the carrier wafer 201. That is, the semiconductor structures 108a-108d of the wafer 204a are between the carrier wafer 201 and the semiconductor substrate 106 along the Z direction.

As shown in FIG. 2B, the semiconductor substrate 106 of the wafer 204a can be thinned, thereby reducing a thickness of the wafer 204a (e.g., a size of the wafer 204a along the Z direction).

As shown in FIG. 2C, a wafer 204b is stacked on and bonded to the wafer 204a. The wafer 204b can be a larger piece of wafer that includes multiple wafers 104b of FIG. 1A. For example, the multiple wafers 104b can be arranged along the Y direction in the wafer 204b.

As shown in FIG. 2D, the semiconductor substrate 106 of the wafer 204b can be thinned.

The process illustrated in FIGS. 2C-2D can be repeated so that more wafers that include semiconductor structures (e.g., wafers 204c-204e as shown in FIG. 2E) can be stacked and bonded to the wafer 204b. As shown in FIG. 2E, a semiconductor structure 200e is formed. The semiconductor structure 200e can include the carrier wafer 201 and the wafers 204a-204c. Each of the wafers 204a-204c can include a thinned semiconductor substrate 106 and semiconductor structures 108a-108d. Each of the semiconductor structures 108a-108d can include a conductive layer 114. The conductive layers 114 of the semiconductor structures that are aligned along the Z direction can form a staircase-like structure.

Any suitable bonding techniques can be applied to the bonding process of the carrier wafer 201 and the wafers 204a-204c. In some implementations, the wafer 204a can be bonded to the carrier wafer 201 using a direct bonding technology (e.g., forming bonding between surfaces without using intermediate layers, such as solder or adhesives). For example, the wafer 204a can include a dielectric layer on its surface (e.g., the surface that is opposite to the semiconductor substrate 106). The carrier wafer 201 can also include a dielectric layer on its surface. The dielectric layer of the wafer 204a can be bonded to the dielectric layer of the carrier wafer 201 using the direct bonding technology (e.g., dielectric-dielectric bonding). Similarly, adjacent wafers of the wafers 204a-204e also can be bonded through dielectric layers using the direct bonding technology.

FIG. 2F illustrates a semiconductor structure 200f. The semiconductor structure 200f can be formed by forming contact structures 112a-112e in the semiconductor structure 200e. The contact structures 112a-112e extend along the Z direction and are coupled to corresponding conductive layers 114 of the semiconductor structures 118a-118d of the wafers 204a-204c. The contact structures 112a-112e can be formed, for example, by forming contact holes that extend through one or more of the wafers 204a-204e and depositing a conductive material into the contact holes.

FIG. 2G illustrates a top view of the semiconductor structure 200f. As shown in FIG. 2G, each of the wafers 204a-204e includes multiple rows 206 of semiconductor structures 108a-108d. The multiple rows 206 are arranged along the Y direction.

FIG. 2H illustrates a semiconductor structure 200h. The semiconductor structure 200h can be formed by adding one or more interconnect layers 110 on top of the semiconductor structure 200f. The interconnect layers 110 can be in contact with the wafer 204e and can extend in the X-Y plane. Each interconnect layer 110 can include interconnects (e.g., lateral interconnect lines 124 and VIA contacts 126) coupled to the contact structures 112a-112e. In some implementations, the interconnect layer 110 is configured to transfer electrical signals to and from one or more rows 206 of semiconductor structures 108a-108d of each of the wafers 204a-204c. For example, the interconnect layer 110 can be configured to provide connections between corresponding rows of semiconductor structures 108a-108d and another device (e.g., a control die 102 and/or an external device).

In some implementations, the interconnect layer 110 includes multiple ILD layers and interconnects therein formed in multiple processes. For example, interconnect lines 124 and VIA contacts 126 can include conductive materials deposited by one or more thin film deposition processes including, but not limited to, CVD, PVD, ALD, electroplating, electroless plating, or any combination thereof. Fabrication processes to form interconnect lines 124 and VIA contacts 126 can also include photolithography, CMP, wet/dry etch, or any other suitable processes. The ILD layers can include dielectric materials deposited by one or more thin film deposition processes including, but not limited to, CVD, PVD, ALD, or any combination thereof.

FIG. 2I illustrates a cross-sectional view of the semiconductor structure 200h along a cut line AA′ of FIG. 2H. As shown in FIG. 2I, the interconnect layers 110 can be arranged along the Y direction. FIG. 2J illustrates a top view of the semiconductor structure 200h. As shown in FIG. 2J, some of the VIA contacts 126 can be exposed from a top surface (e.g., a surface 210 as shown in FIG. 2H) of the interconnect layers 110 and can be connected to another device (e.g., a control die 102) later. FIGS. 2I and 2J illustrate an example, where an interconnect layer 110 is associated with one row 206 of semiconductor structures 108a-108d. In other words, one interconnect layer 110 is coupled to one row 206 of semiconductor structures 108a-108d in each wafer of the wafers 204a-204c through the contact structures 112a-112e. It is understood that in some other implementations, multiple rows 206 of semiconductor structures 108a-108d in each wafer can be coupled to the same interconnect layer 110.

FIG. 2K illustrates a semiconductor structure 200k. The semiconductor structure 200k can be formed by stacking one or more control dies 102 on top of the semiconductor structure 200h. For example, the one or more control dies 102 can be arranged along the Y direction, and each control die 102 can be stacked on and bonded to a corresponding interconnect layer 110. FIG. 2L illustrates a top view of an example semiconductor structure 200k-1. The semiconductor structure 200k-1 can be an example of the semiconductor structure 200k, where a control die 102 (and a corresponding interconnect layer 110) is on top of a row 206 of semiconductor structures 108a-108d of each of wafers 204a-204c. FIG. 2M illustrates a top view of an example semiconductor structure 200k-2. The semiconductor structure 200k-2 can be another example of the semiconductor structure 200k, where a control die 102 (and a corresponding interconnect layer 110) is on top of multiple rows 206 of semiconductor structures 108a-108d of each of wafers 204a-204c. In the semiconductor structures 200k, 200k-1, and 200k-2, each control die 102 can be coupled to one or more rows 206 of semiconductor structures 108a-108d of each of wafers 204a-204c through the corresponding interconnect layer 110 and the contact structures 112a-112e that are connected to the interconnect layer 110.

FIGS. 2L and 2M also illustrate scribe lines 207. The scribe lines 207 can separate each control die 102 and electrical circuits (e.g., the corresponding interconnect layer 110 and the corresponding semiconductor structures 108a-108d) that are associated with the control die 102 from other control dies 102 and other electrical circuits. In a later process, a semiconductor structure that includes multiple bonded wafers can be cut into smaller pieces along the scribe lines 207. Each of the smaller pieces can be an individual semiconductor device (e.g., the semiconductor device 100a of FIG. 1A).

The control dies 102 can be bonded to the semiconductor structure 200h using any suitable bonding techniques. In some implementations, each control dies 102 can be bonded to the semiconductor structure 200h using a die-to-wafer bonding technique. For example, each individual control die 102 can be bonded to a corresponding interconnect layer 110 of the semiconductor structure 200h through conductive contacts. The conductive contacts can be, for example, micro bumps. In some other implementations, the control dies 102 can be bonded to the semiconductor structure 200h using a wafer-to-wafer bonding technique. In other words, the control dies 102 can be bonded to the semiconductor structure 200h as a wafer. A wafer (referred to as a control wafer) that includes the control dies 102 can be provided. Before cutting each individual control die 102 out from the control wafer, the control wafer can be bonded to the interconnect layers 110 of the semiconductor structure 200h. For example, the control wafer can be bonded to the interconnect layers 110 using hybrid dielectric-dielectric and metal-metal bonding. A bonding layer 208a can be formed on bottom surfaces of the control dies 102 of the control wafer. The bonding layer 208a includes conductive bonding contacts 210a and a dielectric material 212a isolating the conductive bonding contacts 210a in the X-Y plane. Another bonding layer 208b can be formed on top of the interconnect layers 110. The bonding layer 208b includes conductive bonding contacts 210b and a dielectric material 212b isolating the conductive bonding contacts 210b in the X-Y plane. The control dies 102 in the control wafer can be bonded to the interconnect layers 110 through the bonding layer 208a and the bonding layer 208b by bonding the conductive bonding contacts 210a to the conductive bonding contacts 210b and bonding the dielectric material 212a to the dielectric material 212b. The conductive bonding contacts 210a and 210b can include conductive materials including, but not limited to, tungsten (W), cobalt (Co), copper (Cu), aluminum (Al), silicides, or any combination thereof. The dielectric materials 212a and 212b can include dielectrics including, but not limited to, silicon oxide, silicon nitride, silicon oxynitride, low-k dielectrics, or any combination thereof.

FIG. 2N illustrates a semiconductor structure 200n. The semiconductor structure 200n can be formed from the semiconductor structure 200k by forming one or more dielectric layers 116 on top of the interconnect layers 110. The dielectric layers 116 can be adjacent to the control dies 102 along the X direction. Conductive pads 118 can be formed in the dielectric layers 116. The conductive pads 118 can be coupled to the interconnect layers 110 and can be exposed from a top surface 220 of the dielectric layers 116. In some implementations, as shown in FIG. 2N, the carrier wafer 201 can be removed or de-bonded from the wafer 204a thereby reducing a thickness of the semiconductor structure 200n.

FIG. 2O illustrates a top view of the semiconductor structure 200n. The semiconductor structure 200n can be cut into smaller pieces along the scribe lines 207. Each individual piece can be a semiconductor device or a semiconductor die that is the same as or similar to the semiconductor devices 100a, 100a-1, and 100a-2 illustrated by FIGS. 1A, IC, and ID, respectively.

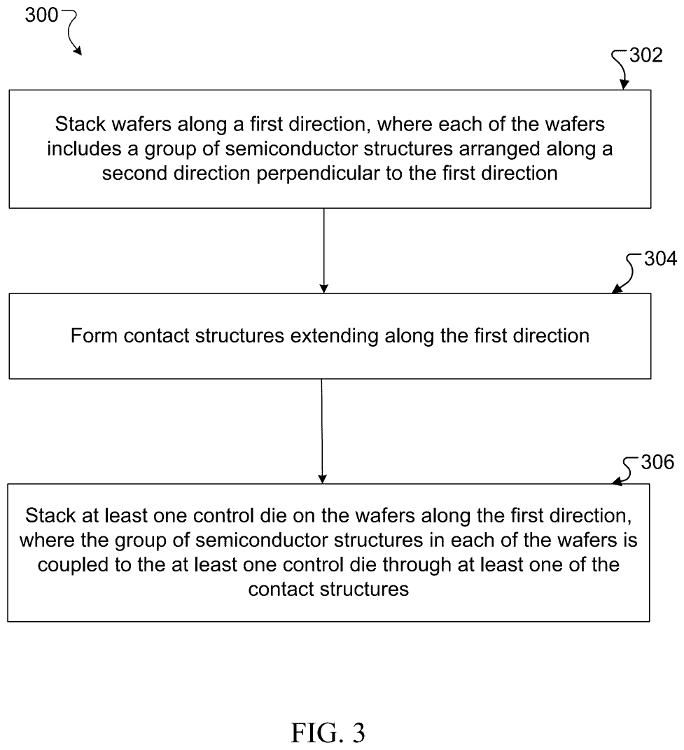

FIG. 3 illustrates a flow chart of an example process 300. The process 300 can be performed to form a semiconductor device. The semiconductor device can be similar to, or same as, the semiconductor device 100a of FIG. 1A, the semiconductor device 100a-1 of FIG. 1C, or the semiconductor device 100a-2 of FIG. 1D. The process 300 can be described in view of FIGS. 2A-2O. The process 300 can include one or more steps of the fabrication process of forming the semiconductor structures in FIGS. 2A-2O. It is understood that the operations shown in process 300 are not exhaustive and that other operations can be performed as well before, after, or between any of the illustrated operations. Further, some of the operations may be performed simultaneously, or in a different order than shown in FIG. 3.

At operation 302, wafers are stacked along a first direction (e.g., the Z direction). The wafers can be similar to, or same as, the wafers 204a-204c of FIGS. 2E, 2F, 2H, 2K, and 2N. Each of the wafers includes a group of semiconductor structures arranged along a second direction (e.g., the X direction) perpendicular to the first direction. The group of semiconductor structures can be similar to, or same as, the semiconductor structures 108a-108d of FIGS. 2E-2O.

At operation 304, contact structures extending along the first direction are formed. The contact structures can be similar to, or same as, the contact structures 112a-112e of FIGS. 2F, 2G, 2H, 2K, and 2N.

At operation 306, at least one control die is stacked on the wafers along the first direction. The at least one control die can be similar to, or same as the control dies 102 of FIGS. 2K, 2L, 2M, 2N, and 2O. The group of semiconductor structures in each of the wafers is coupled to the at least one control die through at least one of the contact structures.

In some implementations, the process 300 further includes forming an interconnect layer (e.g., one of the interconnect layers 110 of FIGS. 2H, 2K, and 2N) on top of the wafers. The at least one control die can be stacked on the interconnect layer.

In some implementations, the wafers include a first wafer (e.g., the wafer 204a of FIG. 2N) and a second wafer (e.g., the wafer 204b of FIG. 2N) stacked on the first wafer. The group of semiconductor structures of the first wafer includes a first semiconductor structure (e.g., the semiconductor structure 108a of the wafer 204a of FIG. 2N) and a second semiconductor structure (e.g., the semiconductor structure 108b of the wafer 204a of FIG. 2N). The group of semiconductor structures of the second wafer includes a third semiconductor structure (e.g., the semiconductor structure 108a of the wafer 204b of FIG. 2N) and a fourth semiconductor structure (e.g., the semiconductor structure 108b of the wafer 204b of FIG. 2N). The contact structures include a first contact structure (e.g., the contact structure 112a that is connected to the semiconductor structure 108a of the wafer 204a), a second contact structure (e.g., the contact structure 112a that is connected to the semiconductor structure 108b of the wafer 204a), a third contact structure (e.g., the contact structure 112b that is connected to the semiconductor structure 108a of the wafer 204b), and a fourth contact structure (e.g., the contact structure 112b that is connected to the semiconductor structure 108b of the wafer 204b) coupled to the first semiconductor structure, the second semiconductor structure, the third semiconductor structure, and the fourth semiconductor structure, respectively.

In some implementations, the process 300 further includes bonding a bonding layer of the second wafer to a bonding layer of the first wafer. The bonding layer of the first wafer and the bonding layer of the second wafer each includes a dielectric material and excludes a conductive bonding contact.

In some implementations, the third contact structure extends into the second wafer and contacts a conductive layer of the third semiconductor structure without extending through the bonding layer of the second wafer. The fourth contact structure extends into the second wafer and contacts a conductive layer of the fourth semiconductor structure without extending through the bonding layer of the second wafer. The first contact structure extends through the bonding layer of the second wafer and the bonding layer of the first wafer and contacts a conductive layer of the first semiconductor structure without extending through the conductive layer of the third semiconductor structure. The second contact structure extends through the bonding layer of the second wafer and the bonding layer of the first wafer and contacts a conductive layer of the second semiconductor structure without extending through the conductive layer of the fourth semiconductor structure.

In some implementations, the process 300 further includes forming a dielectric layer (e.g., the dielectric layer 116 of FIG. 2N) on top of the interconnect layer. The dielectric layer is adjacent to the at least one control die along the second direction. The process 300 further includes forming conductive pads (e.g., the conductive pads 118 of FIG. 2N) in the dielectric layer. The conductive pads can be coupled to the interconnect layer and are exposed from a top surface (e.g., the surface 220 of FIG. 2N) of the dielectric layer. The process 300 further includes forming an integrated structure (e.g., the semiconductor structure 200n of FIG. 2N) including the at least one control die, the wafers, the interconnect layer, and the dielectric layer. The process 300 further includes cutting off a part of the integrated structure to be a semiconductor device. For example, the semiconductor device can be cut out from the integrated structure along scribe lines (e.g., as described with reference to FIG. 2O). The semiconductor device includes a corresponding control die of the at least one control die, a corresponding part of the dielectric layer, a corresponding part of the interconnect layer, and a corresponding part of the group of semiconductor structures of each of the wafers.

In some implementations, the process 300 further includes bonding the first wafer to a carrier wafer (e.g., the carrier wafer 201 of FIG. 2A). For example, the first wafer can be bonded to the carrier wafer before the second wafer is stacked on and bonded to the first wafer.

In some implementations, the process 300 further includes de-bonding or removing the carrier wafer from the first wafer (e.g., as described with reference to FIG. 2N). For example, the carrier wafer can be de-bonded from the first wafer after the dielectric layer is formed on top of the interconnect layer.

In some implementations, the process 300 further includes thinning the first wafer by thinning a substrate (e.g., the semiconductor substrate 106 of the wafer 204a) of the first wafer and thinning the second wafer by thinning a substrate (e.g., the semiconductor substrate 106 of the wafer 204b) of the second wafer. For example, the thinning processes can be similar to, or same as, the process described with reference to FIGS. 2B and 2D.

In some implementations, each of the at least one control die and the interconnect layer includes a bonding layer (e.g., the bonding layers 208a and 208b of FIG. 2K) including conductive bonding contacts and a dielectric material isolating the conductive bonding contacts. The process 300 further includes bonding the at least one control die to the interconnect layer by bonding the dielectric material (e.g., the dielectric material 212a of FIG. 2K) of the bonding layer (e.g., the bonding layer 208a of FIG. 2K) of the at least one control die to the dielectric material (e.g., the dielectric material 212b of FIG. 2K) of the bonding layer (e.g., the bonding layer 208b of FIG. 2K) of the interconnect layer and bonding the conductive bonding contacts (e.g., the conductive bonding contacts 210a of FIG. 2K) of the bonding layer of the at least one control die to the conductive bonding contacts (e.g., the conductive bonding contacts 210b of FIG. 2K) of the bonding layer of the interconnect layer.

In some implementations, the wafers include a third wafer (e.g., the wafer 204c of FIGS. 2E, 2F, 2H, 2K, and 2N) stacked on the second wafer along the first direction.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a control die; and
wafers stacked together along a first direction,
wherein each of the wafers comprises:
a semiconductor substrate extending along a second direction perpendicular to the first direction; and
semiconductor structures on a side of the semiconductor substrate, and
wherein the control die is coupled to the semiconductor structures of each of the wafers by contact structures extending through a corresponding semiconductor substrate of at least one of the wafers along the first direction.

2. The semiconductor device according to claim 1, wherein the semiconductor structures comprise a first row of semiconductor structures arranged along the second direction.

3. The semiconductor device according to claim 2, wherein the semiconductor structures further comprise a second row of semiconductor structures arranged along the second direction, and wherein the first row of semiconductor structures is adjacent to the second row of semiconductor structures along a third direction perpendicular to the first direction and the second direction.

4. The semiconductor device according to claim 1, wherein one of the semiconductor structures of the wafer comprises transistors formed from the semiconductor substrate of the wafer.

5. The semiconductor device according to claim 1, wherein the wafers comprise a first wafer and a second wafer, and wherein the semiconductor device further comprises:
an interconnect layer between the second wafer and the control die, wherein the interconnect layer is coupled to the control die and the contact structures; and
a first bonding layer between the interconnect layer and the control die, wherein the first bonding layer comprises first conductive bonding contacts and a first dielectric material isolating the first conductive bonding contacts.

6. The semiconductor device according to claim 5, further comprising:
a second bonding layer between the first wafer and the second wafer, wherein the second bonding layer comprises a second dielectric material and excludes a conductive bonding contact.

7. The semiconductor device according to claim 5, wherein:
the contact structures comprise a first group of contact structures and a second group of contact structures;
the control die is coupled to the semiconductor structures of the first wafer by the first group of contact structures extending through a semiconductor substrate of the first wafer and a semiconductor substrate of the second wafer; and
the control die is coupled to the semiconductor structures of the second wafer by the second group of contact structures extending through the semiconductor substrate of the second wafer.

8. The semiconductor device according to claim 7, wherein:
each of the second group of contact structures contacts a conductive layer of one of the semiconductor structures of the second wafer; and
each of the first group of contact structures contacts a conductive layer of one of the semiconductor structures of the first wafer without extending through a conductive layer in the second wafer.

9. The semiconductor device according to claim 5, further comprising:
a dielectric layer in contact with the interconnect layer, wherein the dielectric layer is adjacent to the control die along the second direction; and
conductive pads in the dielectric layer, wherein the conductive pads are coupled to the interconnect layer and are exposed from a surface of the dielectric layer.

10. The semiconductor device according to claim 1, wherein the control die is configured to disable a semiconductor structure of a wafer of the wafers in response to detecting a defect of the semiconductor structure.

11. A semiconductor device, comprising:
a control die; and
one or more wafers stacked along a first direction,
wherein each of the one or more wafers comprises:
a semiconductor substrate extending along a second direction perpendicular to the first direction; and
semiconductor structures on a side of the semiconductor substrate, wherein the semiconductor structures comprising rows of semiconductor structures, and
wherein the control die is coupled to the semiconductor structures of each of the wafers by contact structures extending through a corresponding semiconductor substrate of the one or more wafers along the first direction.

12. The semiconductor device according to claim 11, wherein the rows of semiconductor structures comprise a first row of semiconductor structures arranged along the second direction and a second row of semiconductor structures arranged along the second direction, the first row of semiconductor structures is adjacent to the second row of semiconductor structures along a third direction perpendicular to the first direction and the second direction.

13. The semiconductor device according to claim 11, wherein the wafers comprise a first wafer and a second wafer, and wherein the semiconductor device further comprises:
an interconnect layer between the second wafer and the control die, wherein the interconnect layer is coupled to the control die and the contact structures;
a first bonding layer between the interconnect layer and the control die, wherein the first bonding layer comprises first conductive bonding contacts and a first dielectric material isolating the first conductive bonding contacts; and
a second bonding layer between the first wafer and the second wafer, wherein the second bonding layer comprises a second dielectric material and excludes a conductive bonding contact.

14. The semiconductor device according to claim 13, wherein:
the contact structures comprise a first group of contact structures and a second group of contact structures;
the control die is coupled to the semiconductor structures of the first wafer by the first group of contact structures extending through a semiconductor substrate of the first wafer and a semiconductor substrate of the second wafer; and
the control die is coupled to the semiconductor structures of the second wafer by the second group of contact structures extending through the semiconductor substrate of the second wafer.

15. A method, comprising:
stacking wafers along a first direction, wherein each of the wafers comprises a group of semiconductor structures arranged along a second direction perpendicular to the first direction;
forming contact structures extending along the first direction; and
stacking at least one control die on the wafers along the first direction, wherein the group of semiconductor structures in each of the wafers is coupled to the at least one control die through at least one of the contact structures.

16. The method according to claim 15, further comprising:
forming an interconnect layer on top of the wafers, wherein the at least one control die is stacked on the interconnect layer.

17. The method according to claim 16, wherein:
the wafers comprise a first wafer and a second wafer stacked on the first wafer;
the group of semiconductor structures of the first wafer comprises a first semiconductor structure and a second semiconductor structure;
the group of semiconductor structures of the second wafer comprises a third semiconductor structure and a fourth semiconductor structure; and
the contact structures comprise a first contact structure, a second contact structure, a third contact structure, and a fourth contact structure coupled to the first semiconductor structure, the second semiconductor structure, the third semiconductor structure, and the fourth semiconductor structure, respectively.

18. The method according to claim 17, further comprising:
bonding a bonding layer of the second wafer to a bonding layer of the first wafer, wherein the bonding layer of the first wafer and the bonding layer of the second wafer each comprise a dielectric material and excludes a conductive bonding contact.

19. The method according to claim 18, wherein:
the third contact structure extends into the second wafer and contacts a conductive layer of the third semiconductor structure without extending through the bonding layer of the second wafer;
the fourth contact structure extends into the second wafer and contacts a conductive layer of the fourth semiconductor structure without extending through the bonding layer of the second wafer;
the first contact structure extends through the bonding layer of the second wafer and the bonding layer of the first wafer and contacts a conductive layer of the first semiconductor structure without extending through the conductive layer of the third semiconductor structure; and
the second contact structure extends through the bonding layer of the second wafer and the bonding layer of the first wafer and contacts a conductive layer of the second semiconductor structure without extending through the conductive layer of the fourth semiconductor structure.

20. The method according to claim 16, further comprising:
forming a dielectric layer on top of the interconnect layer, wherein the dielectric layer is adjacent to the at least one control die along the second direction;
forming conductive pads in the dielectric layer, wherein the conductive pads are coupled to the interconnect layer and are exposed from a top surface of the dielectric layer;
forming an integrated structure comprising the at least one control die, the wafers, the interconnect layer, and the dielectric layer; and
cutting off a part of the integrated structure to be a semiconductor device, wherein the semiconductor device comprises a corresponding control die of the at least one control die, a corresponding part of the dielectric layer, a corresponding part of the interconnect layer, and a corresponding part of the group of semiconductor structures of each of the wafers.
